(19) United States
(12) Patent Application Publication
(10) Pub. No.: US 2005/0199183 A1
(43) Pub. Date: Sep. 15, 2005

(54) Plasma processing apparatus

(76) Inventors: Masatsugu Arai, Ibaraki-ken (JP); Tsutomu Tetsuka, Ibaraki-ken (JP); Hiroyuki Kitsunai, Ibaraki-ken (JP); Muneo Furuse, Kudamatsu-shi (JP); Masanori Kadotani, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/795,329

(22) Filed: Mar. 9, 2004

(51) Int. Cl. C23C 16/00

(52) U.S. Cl. 118/715

(57) ABSTRACT

The purpose of the invention is to provide a plasma processing apparatus capable of processing a substrate stably for a long period of time. The present plasma processing apparatus for processing a substrate placed on a substrate holder disposed in a processing chamber using a plasma generated in the processing chamber comprises at least one member detachably mounted on an inner wall surface of the processing chamber having a portion coated with a material different from a material coating the other portion.

### FIELD OF THE INVENTION

The present invention relates to a plasma processing apparatus to be used in micromachining of a semiconductor manufacturing process and the like, and especially relates to a plasma processing apparatus that is capable of suppressing the damage to the wall surfaces of a processing chamber, and that is capable of carrying out stable micromachining for a long period of time.

### DESCRIPTION OF THE RELATED ART

Conventionally, plasma processing apparatuses such as plasma CVD apparatuses and plasma etching apparatuses are used widely as semiconductor manufacturing apparatuses, for manufacturing semiconductor devices by processing plate members such as silicon wafers to be processed (hereinafter referred to as wafers). Recently, along with the enhancement in the integration of devices, the circuit patterns have become more and more refined, and the required accuracy for the dimension of the processing by the plasma processing apparatuses has become very strict. Further, along with the diversification in the materials constituting the device, the etching recipes have become complex, and the stability of the processes for long-term mass production has become a serious problem. For example, in a plasma processing apparatus, plasmas generated with reactive gases such as fluoride, chloride and bromide are used, so the surface of the walls of the processing chamber are eroded both chemically and physically. Therefore, along with the increase in the number of wafers being processed, the chemical composition or the high-frequency transmission property within the processing chamber is gradually varied, and in some cases, it becomes impossible to perform a long-term stable processing. Further, the material constituting the eroded wall surface of the processing chamber may chemically react with the active radicals in the plasma, and may cause deposits to adhere on the inner walls of the chamber. The thickness of deposits adhered on the inner walls increases through repeated etching, and in the worst case, the deposits may fall from the walls onto the wafer, creating defective products.

In order to cope with this problem, according to a typical solution, the surface of the inner wall of the processing chamber and the members therein such as a stage of the plasma processing apparatus are subjected to an anodization treatment (so-called an alumite treatment) that provides high stability to chemical reaction (the thickness of the alumite being 20 micrometers in general). However, it has been pointed out that the plasma-resisting property of alumite is not sufficient when attempting to carry out processing in a stable manner for a longer period of time.

Therefore, another solution has been considered, according to which a material having resistance to plasma is coated on the inner walls of the processing chamber of the plasma processing apparatus. For example, according to Japanese patent application laid-open No. 2002-252209 (patent reference 1), an yttrium fluoride (YF₃) is applied to the surface of the members disposed within the processing chamber, or sintered yttrium fluoride is used as material for forming the members.

Furthermore, Japanese Patent No. 3426825 (patent reference 2) discloses coating at least the surface of the inner walls of the processing chamber of the plasma processing apparatus with one element of or a compound composed of elements of group 2A of the periodic table.
Patent reference 1: JP Application Laid-Open No. 2002-252209
Patent reference 2: JP No. 3426825

According to the prior art, the alumite material that has been widely used did not have sufficient resistance to plasma to ensure stable processing to be performed for a long period of time. Further, it has been pointed out that the aluminum generated from the alumite material in the chamber being etched during processing causes contaminants to adhered to the surface of the semiconductor wafer or object being processed.

Furthermore, the arts disclosed in patent references 1 and 2 may be effective from the viewpoint of resistance to plasma, but they lack considerations on heat resistance, durability, long lifetime and mass fabrication property of the members in the chamber. Therefore, it cannot be said that the disclosed arts draw out the effects of the plasma-resistant material sufficiently.

For example, according to the arts disclosed in references 1 and 2, the unevenness or bias of potentials of the plasma with respect to the substrate or semiconductor wafer being chucked onto the electrode on the substrate holder causes a specific portion to be subjected to greater plasma injection than the other portions, and the specific portion is chipped thereby. In other words, the portion subjected to concentrated plasma injection greatly affects the timing of replacement of a member, and as a result, the operation efficiency of the apparatus, and causes the member to be replaced even if it is still not time to replace the other portions of the member. The arts disclosed in patent references 1 and 2 do not consider this problem.

Moreover, according to the above-mentioned prior arts, the design of the members disposed in the processing chamber and exposed to plasma was not determined after sufficient consideration of the deformation of components subjected to plasma.

Further, the above-mentioned prior arts lack sufficient consideration on the appropriate structure of the processing chamber for facilitating the operation for mounting a member having resistance to plasma in the processing chamber.

### SUMMARY OF THE INVENTION

The object of the present invention is to provide a plasma processing apparatus capable of processing a substrate stably for a long period of time.

Therefore, the present invention provides a plasma processing apparatus for processing a substrate placed on a substrate holder disposed in a processing chamber using a plasma generated in the processing chamber, wherein the plasma processing apparatus comprises at least one member detachably mounted on an inner wall surface of the processing chamber and having a portion coated with a material different from the material of the other portions.

According further to the plasma processing apparatus of the present invention, a surface of the member that comes into contact with plasma is coated with a material having resistance to plasma and comprising Y₂O₃, Yb₂O₃ or YF₃, or a mixture thereof, as its main component.

According to another aspect of the plasma processing apparatus of the present invention, the surface of the member that comes into contact with plasma is coated with a material having high resistance to plasma, and a surface on the side to be mounted on the processing chamber of the member is coated with a material having higher strength than the material or the mixture of materials having high resistance to plasma.

According to another aspect of the plasma processing apparatus of the present invention, a boundary between an alumite coating and the Y₂O₃, Yb₂O₃ or YF₃ coating on the surface of the member is overlapped so that each of the coatings is gradually thickened or thinned, and the boundary is constructed-so that the Y₂O₃, Yb₂O₃ or YF₃ coating overlaps the alumite coating.

According to another aspect of the plasma processing apparatus of the present invention, the apparatus comprises a member that forms an inner wall surface of the processing chamber and detachably mounted to the interior of the processing chamber, wherein a surface of the member is coated with a coating, and the thickness of the coating is thicker at a corner portion than at a planar portion of the surface of the member.

According to yet another aspect of the plasma, processing apparatus of the present invention, the Y₂O₃, Yb₂O₃ or YF₃ is coated via spray coating, and the coating is subjected to a sealing treatment using fluorocarbon resin, SiO₂, polyimide, silicon or the like.

### BRIEF DESCRIPTION OF THE DRAWINGS

FIG. 1 is a cross-sectional view showing a plasma processing apparatus according to one embodiment of the present invention;

FIG. 2 is a cross-sectional view showing a processing chamber 100 in the plasma processing apparatus according to one embodiment of the present invention;

FIG. 3 is a chart comparing the etching rate in chlorine plasma of alumite, Al₂O₃ formed by sintering, and Al₂O₃, Yb₂O₃ and YF₃ formed by spraying;

FIG. 4 is a chart showing the relationship between the RF power of an electrostatic chucking electrode and the etching rate of alumite;

FIG. 5 is a cross-sectional view of an earth cover according to one embodiment of the present invention;

FIG. 6 is an explanatory view showing the cross-sectional appearance of a spray coating according to one embodiment of the present invention;

FIG. 7 is a cross-sectional view showing an example of an earth cover according to one embodiment of the present invention;

FIG. 8 is a view showing the steps for forming the earth cover according to one embodiment of the present invention;

FIG. 9 is a view showing the profile of the boundary between the spray coating and the alumite according to one embodiment of the present invention; and

FIG. 10 is a view showing the cross-section of an etched portion of the earth cover according to one embodiment of the present invention.

### DETAILED DESCRIPTION OF THE PREFERRED EMBODIMENT

Now, the preferred embodiments of the plasma processing apparatus according to the present invention will be described in detail with reference to the drawings.

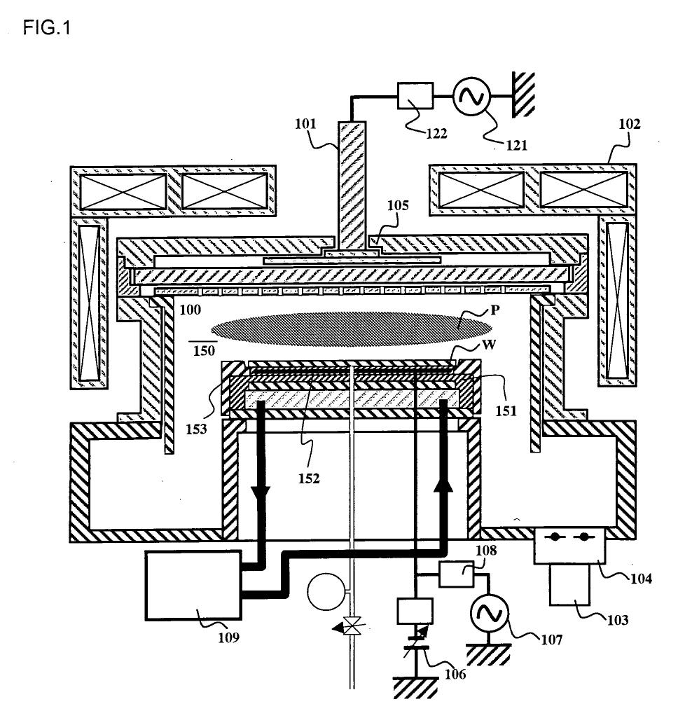

FIG. 1 is a cross-sectional view of a plasma processing apparatus according to one embodiment of the present invention. The plasma processing apparatus illustrated in FIG. 1 is equipped with a processing chamber 100, an antenna 101 disposed above the processing chamber 100 for radiating electromagnetic waves, and a support stage 150 disposed at the lower area thereof for mounting a substrate to be processed such as a semiconductor wafer W. The antenna 101 is supported on a housing 105 that constitutes a portion of a vacuum container, and the antenna 101 is disposed substantially parallel to and in confronting relation with the support stage 150.

A magnetic field forming means 102 composed of an electromagnetic coil and a yoke, for example, is disposed around the processing chamber 100.

The support stage 150 is a member generally so-called an electrostatic chucking electrode. As illustrated in FIG. 1, the support stage 150 formed of an electrostatic chucking electrode is composed of an electrode block 151 made of aluminum, a dielectric film 152, and an electrode cover 153 made of alumina. Although not shown, a passage 4 through which circulates a refrigerant supplied thereto with a determined temperature from a temperature control unit 109 is formed within the electrode block 151. The electrode cover 153 made of alumina is a cover for protecting the dielectric film 152. The support stage 150 or electrostatic chucking electrode is designed to have a diameter size of 340 mm and an overall thickness of 40 mm, if a semiconductor wafer W of 12 inches (diameter of 300 mm) is to be processed. A high voltage power supply 106 and a bias power supply 107 are connected to the electrode block 151. The dielectric film 152 is provided with a linear slit extending radially and plural concentric slits communicated therewith. A gas introduction hole is formed in communication with the slits on the dielectric film 152, and He gas for conducting heat is introduced through the introduction hole for enabling heat conduction between the slits (and the dielectric film 152) and the semiconductor wafer W which is the substrate to be processed mounted thereon, so that a He gas with an even pressure (normally around 1000 Pa) is filled to the back surface of the semiconductor wafer W.

The dielectric film according to the present embodiment is constructed of an alumina ceramics with a thickness of 0.1 mm formed via spray coating, but the material and thickness of the dielectric film 152 is not limited to such embodiment, and for example, in the case of a synthetic resin material, the thickness can be selected between a range of 0.1 mm to a several mm. Further, an electrode formed in the shape of a thin film is disposed within the dielectric film 152, and a voltage is applied to the electrode for attracting and holding the semiconductor wafer W or substrate to be processed on the dielectric film 152 (support stage 150).

The processing chamber 100 is a vacuum container capable of realizing a vacuum with a pressure of 1/10000 Pa through an evacuation system 103. The processing gas used to perform processes such as etching and film deposition of the substrate is supplied from a gas supply means not shown into the processing chamber 100 with a determined flow rate and mixture ratio, and the pressure within the processing chamber 100 is controlled via the evacuation system 103 and an evacuation control means 104. According to the present type of plasma processing apparatuses, in general, the processing pressure during etching is controlled typically within the range of 0.1 Pa to 10 Pa.

An antenna power supply 121 is connected to the antenna 101 via a matching circuit 122. The antenna power supply 121 is for supplying a power with a frequency in the UHF band, from 300 MHz to 1 GHz, and according to the present embodiment, the frequency of the antenna power supply 121 is set to 450 MHz. A high-voltage power supply 106 for electrostatic chucking and a bias power supply 107 for supplying bias power within the range of 200 kHz to 13.56 MHz, for example, are connected to the electrostatic chucking electrode S respectively via a matching circuit 108. Further, a temperature control unit 109 for controlling the temperature is connected to the electrostatic chucking electrode S. According to the present embodiment, the frequency of the bias power supply 107 is set to 2 MHz.

According to such etching apparatus, plasma is efficiently generated by the etching gas introduced to the processing chamber by the interaction between the electric field formed by high frequency waves and the magnetic field formed by the magnetic filed coil. Upon performing the etching process, the energy of ions within the plasma being incident on the wafer is controlled by the high-frequency bias power, by which the desired etching profile is achieved.

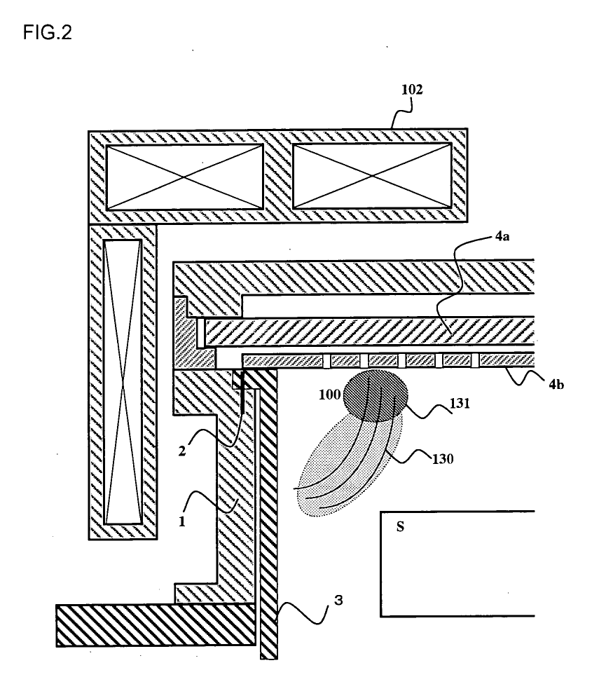

Next, the structure of the processing chamber 100 will be explained with reference to FIG. 2. FIG. 2 illustrates in detail the cross-section of a processing chamber 100 of the plasma processing apparatus according to the present invention. The processing chamber 100 comprises a chamber 1 with an inner diameter of 600 mm and having at least its side wall made of aluminum, an earth cover 3 connected to the chamber 1 via a bolt 2, a quartz plate 4a formed of quartz having a thickness of 25 mm, and a shower plate 4b placed directly below the quartz plate 4a.

A YB₂O₃ with a purity of 99.9% is sprayed onto the surface of the earth cover 3 coming into contact with plasma so as to coat the same by reasons described later. An alumite coating is provided to the surfaces of other portions. According the processing chamber having such a structure, the earth cover 3 is formed as a member capable of being separated from the chamber 1, so the replacement of the earth cover 3 or other processes of cleaning to be performed within the processing chamber is facilitated, and the time required for the cleaning operation can be cut down, and as a result, the operation efficiency of the plasma processing apparatus can be improved.

In the plasma processing apparatus as according to the present embodiment, lines of magnetic force 130 as illustrated in FIG. 2 are formed by the magnetic field forming means 102 composed of an electromagnetic coil and a yoke. Thus, by the high-frequency waves applied from the antenna and the lines of magnetic force 130, high density plasma 131 is generated directly below the shower plate 4b. Further, since the generated plasma is bound by the lines of magnetic force 130, the density of plasma at the surface of the earth cover 3 that is positioned along the extension of the lines of magnetic force 130 is also high. At this time, in the plasma processing apparatus, an electric circuit is formed by the bias power supply for supplying bias power, the support stage 150 serving as electrostatic chucking electrode, the plasma and the surface of the earth cover 3. In this circuit, the earth cover surface where plasma density is high serves as the ground plane. On the surface of the earth cover 3 serving as the ground plane, the electrons in the plasma move at high speed, so the ions being left behind form an electric filed, that is, an ion sheath, in a stable manner. Therefore, the ion sheath (electric field) causes the ions in the plasma to be incident on the earth cover 3, and the earth cover is significantly eroded. Further, the active radicals in the plasma cause corrosion thereof.

According to the prior art plasma processing apparatuses, anodizing (alumite) processes were performed widely to create materials having resistance to plasma, but there are demands for materials that enable plasma processing to be performed stably for a longer period of time. Therefore, experiments were performed to evaluate the resistance to plasma of alumite as current inner wall material, and Yb₂O₃, Y₂O₃ and YF₃, which were chosen from various possible materials and confirmed that they do not affect the device when applied as inner wall material of the etching apparatus. Further, the plasma resistance of Al₂O₃ formed via sintering and having the same composition as alumite (noncrystalline Al₂O₃), and of Al₂O₃ formed via spraying, were evaluated. In the experiment, Yb₂O₃, Y₂O₃ and YF₃ were coated via spraying.

In the experiment for evaluating the plasma resistance, test pieces, each having a 20 mm-square size, were prepared. Each test piece had alumite or spray coating with a thickness of 0.2 to 0.5 mm disposed on the surface of high-purity aluminum with a thickness of 5 mm, and the test piece for the sintered material was formed to have a thickness of 0.5 mm. In the experiment, the test pieces were adhered to the surface of the wafer with conductive adhesives. Thereafter, the wafer was delivered into the plasma processing apparatus, and was exposed to plasma for a predetermined time. After completing the process, the etching rates were measured and the surface appearances were observed. Though the thickness of the test pieces differ among materials, within the range of the present experiment, the amount of ions entering the test pieces does not depend on the thickness of the material but depend on the resistance of the ion sheath and the high frequency power being loaded thereto, so the thickness of the test pieces does not affect the experiment.

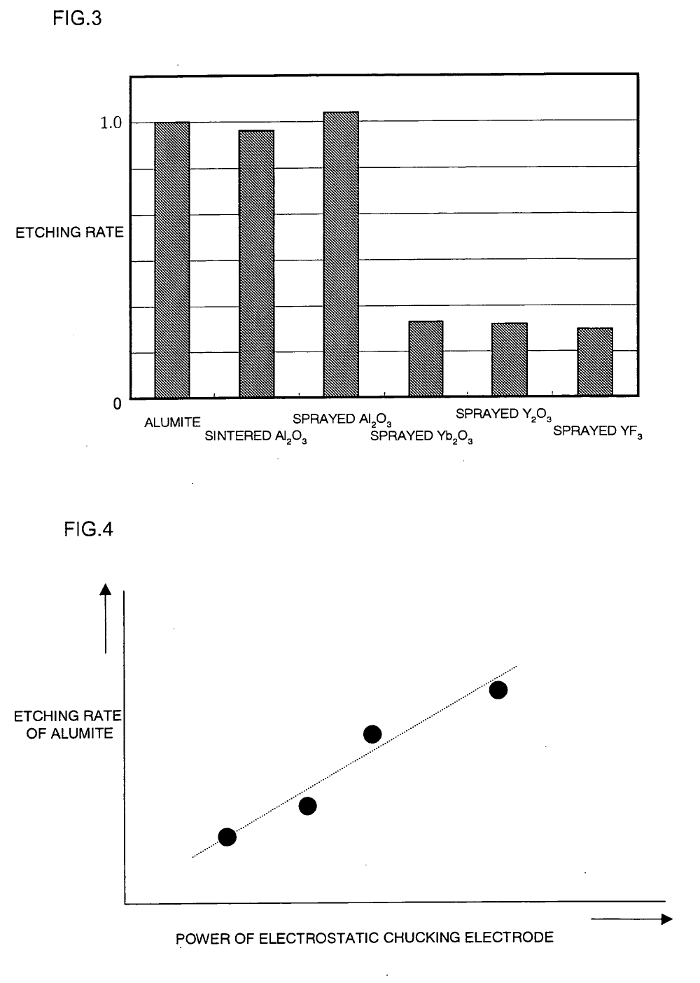

One example of the results of the experiment is illustrated in FIG. 3, which shows the etching rate of the etching performed in chlorine gas plasma. The chart shows the result of the etching operation performed in the etching apparatus shown in FIG. 1 with the pressure set to 0.5 Pa, the Cl₂ flow rate to 150 ml/min, the UHF power to 500 W, and the RF power of electrostatic chucking electrode to 100 W. From the chart shown in FIG. 3, it is recognized that the etching rates of alumite, sintered Al₂O₃ and the sprayed Al₂O₃ were substantially the same with little difference. Further, the etching rates of Y₂O₃, Yb₂O₃ and YF₃ were approximately one-third the etching rates of alumite and Al₂O₃. The surfaces of the test pieces were observed before and after the experiment with an electron microscope, but the appearances of the surfaces were smooth for all the test pieces, and there was no surface with an appearance that indicated the occurrence of a significant chemical reaction. Similar results were achieved through experiments performed under various other conditions using fluorine-based and chlorine-based gases.

FIG. 4 shows the relationship between the RF power of the electrostatic chucking electrode and the etching rate of alumite. The chart shows the variation of the etching rate when the RF power of the electrostatic chucking electrode is varied under the conditions explained in FIG. 3. It is recognized from this chart that the etching rate increases as the RF power increases. This is because the etching rate is determined by the erosion caused by sputtering. Therefore, the reason why the etching rates of alumite, sintered Al₂O₃ and sprayed Al₂O₃ were substantially equal, and why the etching rates of Y₂O₃, Yb₂O₃ and YF₃ were one-third the etching rate of Al₂O₃, was because the etching rate was determined by the erosion caused mainly by sputtering. Thus, it is conceivable that heavier elements are more preferable as the material for forming the wall surface of the processing chamber.

FIG. 5 shows a cross-sectional view of an earth cover 3 to be applied to the plasma processing apparatus according to the present embodiment. The earth cover 3 shown in the drawing has a Yb₂O₃ coating 31 with a purity of 99.9% and a thickness of 200 microns formed via spraying on the surface that comes into contact with plasma (hereinafter referred to as Yb spray coating), and an alumite coating 2 with a thickness of 20 microns is provided to the remaining surface.

As described above, the Yb spray coating 31 has a lower sputter rate than the alumite coating 32 (amorphous Al₂O₃) since the element thereof is heavier, so it is preferable to provide a Yb spray coating 31 to the surface of the earth cover 3. On the other hand, it has been discovered that spray coating should not be applied to a wider area than necessary in order to create a preferable plasma processing apparatus. This is because the spraying method involves spraying fine particles that are heated to very high temperature onto the object surface with high speed, so the surface of the formed spray coating becomes uneven, and if the member applied with the coating has a strict tolerance for the contact surface or the dimension, it becomes necessary to grind the surface after applying the coating. Therefore, the cost and the time for manufacturing wafers are increased.

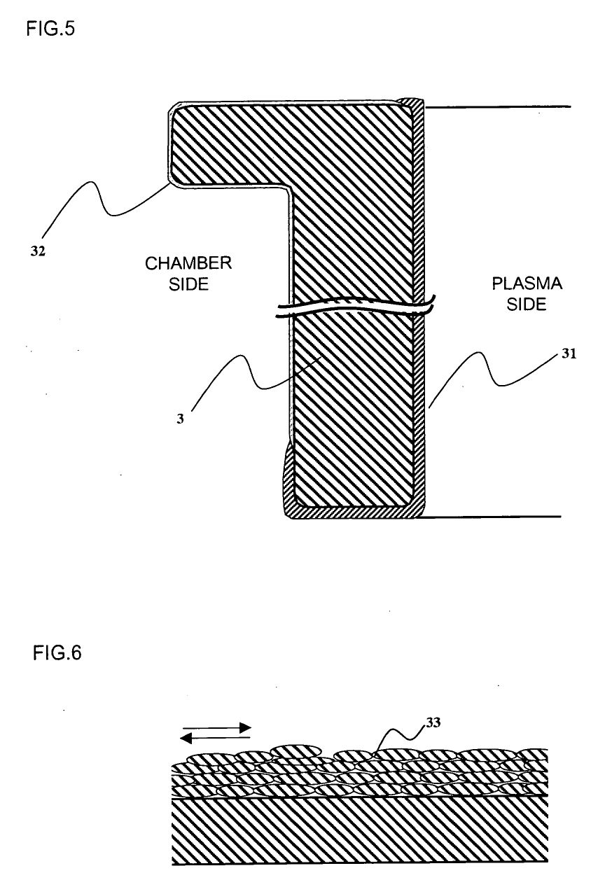

Moreover, since the spray coating is formed by layers of half-melted particles 33, as shown in FIG. 6, from the viewpoint of strength and reliability, it is difficult for the coating to have sufficient shear strength, and the coating material tends to be detached from the surface. For instance, the shear strengths of alumite and spray coating were compared, and it was confirmed that the shear strength of alumite was substantially five times greater than that of the spray coating. Therefore, in the bolt connect area or other similar areas of the earth cover 3, shearing force occurs when the earth cover 3 expands by the heat from the plasma, by which the spray coating may be detached from the earth cover. This detached spray coating may affect the process being performed to the semiconductor wafer.

On the other hand, the manufacture of alumite is easier than the manufacture of the Yb coating, and the strength thereof can be made much greater. For instance, the alumite is grown by chemical reaction in an electrolytic solution, so the hardness and thickness of the coating being formed can be controlled by selecting appropriate processing conditions. Moreover, since the alumite is grown in a columnar structure, it is strong against shearing force and will not cause excessive cracks when applied to areas such as the bolt connect area.

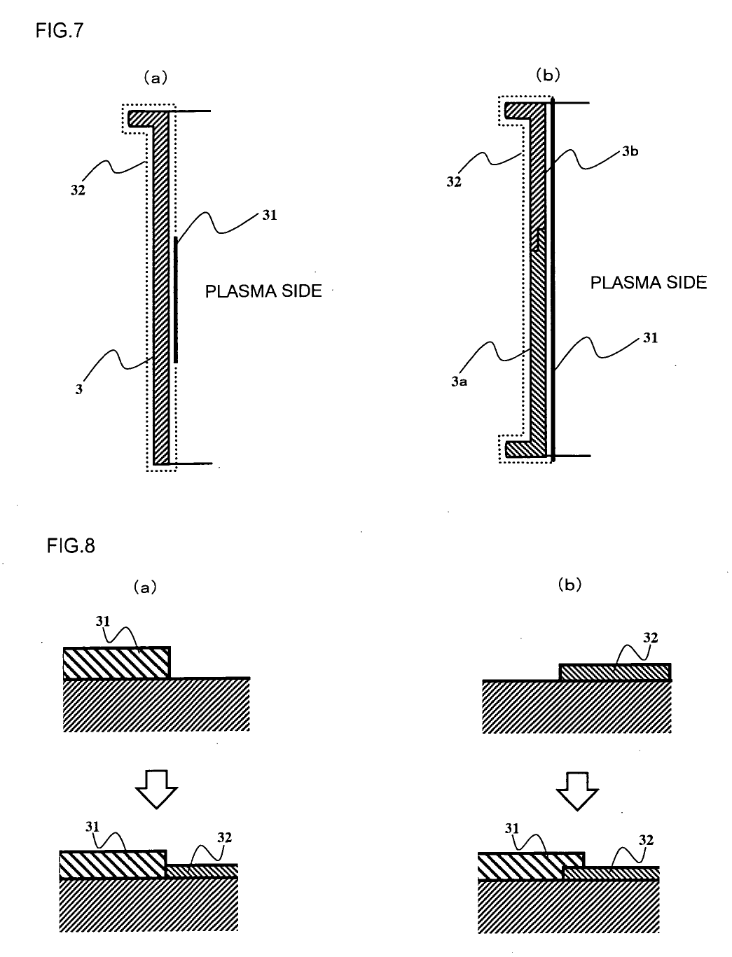

According to reasons mentioned above, it is preferable to provide a coating with a material having advantageous resistance to plasma, such as Yb₂O₃, Y₂O₃ or YF₃, to the surface exposed to plasma, and to provide an alumite coating that has advantageous strength and that can be easily formed to the desired thickness to the surface that is not exposed to plasma. Further, the shape of the earth cover 3 is not limited to the one shown in FIG. 5, and the material having resistance to plasma such as Yb₂O₃, Y₂O₃ or YF₃ can be disposed to cover only the portion that is subjected to extreme erosion by plasma, as shown in FIG. 7(a). The cover can also have a separable structure so as to enhance the handling and the recycling properties, as shown in FIG. 7(b). Furthermore, the earth cover 3 can include one member having its surface coated with a material having advantageous resistance to plasma, such as Yb₂O₃, Y₂O₃ or YF₃, that is formed separately from other members, and the earth cover can be formed by assembling the members.

Next, the profile structure of the boundary between the alumite and the spray coating will be described.

An alumite treatment is a process for forming an oxide coating to an aluminum (Al) surface through electrolysis performed in a diluted sulphuric acid or an oxalic acid solution with the aluminum serving as an anode. On the other hand, a spray coating is formed by spraying heated particles onto a surface. The adhesion strength depends mainly on an anchoring effect. The steps for disposing the alumite and the spray coating to the earth cover 3 are shown in FIG. 8. FIG. 8(a) shows an example in which the spray coating is applied before the alumite is formed, and FIG. 8(b) shows an example in which the spray coating is applied after the alumite is formed.

As shown in FIG. 8(a), if the spray coating 31 is formed before the alumite coating 32 is formed, the boundary between the two coatings becomes clear, and a crack tends to occur at the boundary during heating. Further, there is fear that the electrolytic solution used to create the alumite coating may penetrate into the spray coating and remain therein. On the other hand, as shown in FIG. 8(b), if the spray coating 31 is formed after creating the alumite coating 32, the spray coating 31 is disposed so as to cover a portion of the alumite coating 32, according to which the boundary between the two coatings become unclear, and the formation of cracks can thereby be prevented. Furthermore, upon applying a spray coating 31 on top of the alumite coating 32, the surface of the alumite coating should be somewhat roughened so as to increase the anchoring effect and to improve the adhesion property.

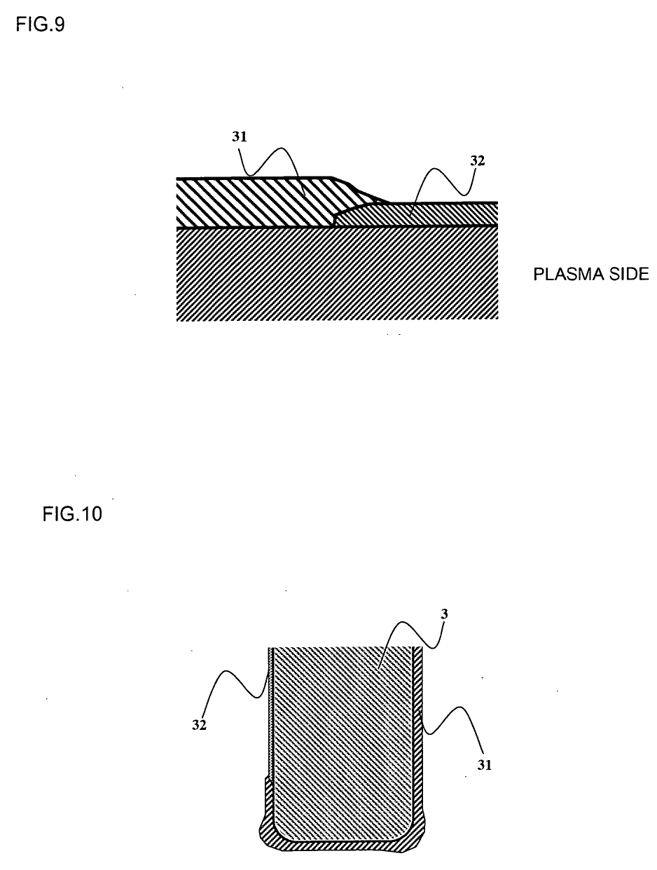

Further, it is preferable that the boundary between the alumite coating 32 and the spray coating 31 has a structure as shown in FIG. 9. As illustrated, by forming the boundary so that each of the alumite coating and the spray coating is respectively gradually thinned or thickened, the thermal expansion coefficient of the two coatings are varied gradually, and the resistance of the coating to heat is improved significantly. It is especially preferable to form the coatings to have such a structure at the edges where the shape is discontinuous.

Since the corners of the earth cover 3 of the present embodiment are formed as singular points, the electric field tends to concentrate on the corners. In the plasma processing apparatus of the present embodiment, the plasma density above the earth ring is high, so the sputter rate at that area is also high (for instance, depending on plasma conditions, it has been confirmed that the sputter rate substantially doubles in this area). Therefore, the erosion is greater at the edges compared to the other areas. When the aluminum base material is exposed at even a small portion on the surface of the earth cover 3, the earth cover 3 must be replaced even if the other areas still have sufficient durability to plasma and are usable. Therefore, the durability of the corner portions that are exposed to plasma determines the overall life of the earth cover 3, the operating rate and the efficiency of the apparatus.

According to the present embodiment, by forming the spray coating 31 to be thicker at the corner edges of the earth cover 3 than at the other areas of the earth cover, as illustrated in FIG. 10, the overall life of the earth cover 3, and therefore the replacement cycle, is elongated. It is especially effective to have the thickness of the spray coating 31 increased at the corner portion of the earth cover 3 that is close to the semiconductor wafer W or the support stage 150. It is possible to form the spray coating 31 to be thicker at the corners of the earth cover 3 by spraying one side of a corner including the corner and then spraying the adjacent side of the corner including the corner, by which the corner area is sprayed several times.

Since the spray coating is multilayered, cavities are formed in the boundary between the layers. These cavities tend to adsorb moisture, so if the sprayed member is disposed in vacuum without modification, the evacuation takes much time due to the release of adsorbed moisture. Further, the chlorine gas or the like used in plasma may be adsorbed in the cavities of the spray coating, and by exposing the processing chamber to the atmosphere, the chlorine may react with the moisture in the air and cause corrosion of the base material. Therefore, it is important to provide a sealing treatment to fill the cavities. The material of the sealing member should be selected from the viewpoint of not affecting the etching process, and not so much its resistance to plasma, since the sealing material will not be exposed to direct ion attacks. The preferable materials include fluorocarbon polymer, SiO₂, polyimide and silicon.

1. A plasma processing apparatus for processing a substrate placed on a substrate holder disposed in a processing chamber using a plasma generated in the processing chamber, said apparatus comprising:
at least one member detachably mounted on an inner wall surface of the processing chamber and having a portion coated with a material different from a material coating the other portion.

2. The plasma processing apparatus according to claim 1, wherein
a surface of said member that comes into contact with plasma is coated with a material having resistance to plasma and comprising Y₂O₃, Yb₂O₃ or YF₃, or a mixture thereof, as its main component.

3. The plasma processing apparatus according to claim 1, wherein
the surface of said member that comes into contact with plasma is coated with a material or a mixture thereof having high resistance to plasma, and a surface on a side to be mounted on the processing chamber of said member is coated with a material having higher strength than said material or the mixture of materials having high resistance to plasma.

4. The plasma processing apparatus according to claim 1 or claim 2, wherein
a boundary between an alumite coating and said Y₂O₃, Yb₂O₃ or YF₃ coating on the surface of said member is overlapped so that each of the coatings is gradually thickened or thinned, and said boundary is constructed so that the Y₂O₃, Yb₂O₃ or YF₃ coating overlaps the alumite coating.

5. A plasma processing apparatus for processing a substrate placed on a substrate holder disposed in a processing chamber using a plasma generated in the processing chamber, said apparatus comprising:
a member that forms an inner wall surface of the processing chamber and is detachably mounted to the interior of the processing chamber, wherein a surface of said member is coated with a coating, and the thickness of said coating is thicker at a corner portion than at a planar portion of the surface of said member.

6. The plasma processing apparatus according to claim 2 or claim 4, wherein
said Y₂₀₃, Yb₂O₃ or YF₃ is coated via spray coating, and the coating is subjected to a sealing treatment using fluorocarbon resin, SiO₂, polyimide, silicon or the like.
